(19) United States
(12) Patent Application Publication
(10) Pub. No.: US 2025/0062755 A1
(43) Pub. Date: Feb. 20, 2025

(54) APPARATUS AND METHOD FOR COMPENSATING FOR PHASE DELAY OF RESOLVER SIGNAL

(71) Applicants: HYUNDAI MOBIS CO., LTD., Seoul (KR); HYUNDAI MOTOR COMPANY, Seoul (KR); Kia Corporation, Seoul (KR)

(72) Inventors: Won Hee JO, Yongin-si (KR); Hyung Min PARK, Yongin-si (KR); Joo Won PARK, Yongin-si (KR); Yeon Ho KIM, Yongin-si (KR); Beom Cheol CHO, Yongin-si (KR); Yun Ho CHOI, Yongin-si (KR); Tae Hwan KANG, Yongin-si (KR); Do Hyeon HAM, Hwaseong-si (KR)

(73) Assignees: HYUNDAI MOBIS CO., LTD., Seoul (KR); HYUNDAI MOTOR COMPANY, Seoul (KR); Kia Corporation, Seoul (KR)

(21) Appl. No.: 18/799,572

(22) Filed: Aug. 9, 2024

(30) Foreign Application Priority Data
Aug. 16, 2023 (KR) 10-2023-0106953

(51) Int. Cl. H03K 5/01; G01D 5/244; H03K 5/00

(52) U.S. Cl. CPC H03K 5/01; G01D 5/2448; H03K 2005/00019

(57) ABSTRACT

Disclosed are an apparatus and a method for compensating for a phase delay of a resolver signal. The apparatus includes an input/output interface, and a processor connected to the input/output interface, wherein the processor receives a command signal and the resolver signal through the input/output interface, calculates a delay time of the resolver signal with respect to the command signal based on the command signal and the resolver signal, calculates a compensation time based on the delay time, and compensates the command signal based on the compensation time.

### CROSS-REFERENCE TO RELATED APPLICATION

This application claims the benefit of priority to Korean Patent Application No. 10-2023-0106953, filed in the Korean Intellectual Property Office on Aug. 16, 2023, the entire contents of which are incorporated herein by reference.

### TECHNICAL FIELD

The present disclosure relates to an apparatus and a method for compensating for the phase delay of a resolver signal, and more particularly, to an apparatus and a method capable of compensating for the phase delay of a resolver signal.

### BACKGROUND

Generally, in order to drive an AC motor of a vehicle at the maximum torque, the angle of the motor rotor must be determined, and a resolver is used for this purpose. A resolver is a type of rotating electrical transformer used to measure the rotation angle of a motor. The resolver may be connected to a microcomputer and an interface device. The microcomputer may generate a command signal of a specified frequency and output it to the interface device. The interface device may generate an excitation signal based on the command signal and output the generated excitation signal to the resolver. The resolver may generate a resolver signal by modulating the excitation signal according to rotation.

Meanwhile, a signal delay may occur in the process of generating a resolver signal, and as a result, the resolver signal output from the resolver may be delayed compared to the command signal output from the microcomputer. The delay time of the resolver signal with respect to the command signal may differ depending on the type of resolver, and there may be deviations even for the same type of resolver due to manufacturing tolerances.

According to the related art, the delay time is compensated by designing the microcomputer software such that the delay time measured immediately after manufacturing the vehicle is applied when calculating the angle of the resolver. However, in such a conventional scheme, the delay time must be measured for each vehicle (motor), which requires excessive manpower and time.

### SUMMARY

The present disclosure has been made to solve the above-mentioned problems occurring in the prior art while advantages achieved by the prior art are maintained intact.

An aspect of the present disclosure provides an apparatus and a method for compensating for a phase delay of a resolver signal, which are capable of compensating for the phase delay of the resolver signal by calculating the delay time of the resolver signal with respect to a command signal output from a microcomputer and compensating the command signal according to the calculated delay time.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an apparatus for compensating for a phase delay of a resolver signal includes an input/output interface, and a processor connected to the input/output interface, wherein the processor receives a command signal and the resolver signal through the input/output interface, calculates a delay time of the resolver signal with respect to the command signal based on the command signal and the resolver signal, calculates a compensation time based on the delay time, and compensates the command signal based on the compensation time.

According to an embodiment, the processor may calculate the delay time after a preset time has elapsed from a time point at which a motor is driven.

According to an embodiment, the processor may detect a frequency of the command signal, calculate a period of the command signal based on the detected frequency, and calculate a value obtained by subtracting the delay time from the calculated period as the compensation time.

According to an embodiment, the processor may synchronize a phase of the command signal and a phase of the resolver signal by delaying the command signal for the compensation time.

According to an embodiment, the processor may compare the resolver signal with a preset reference voltage, detect an edge in a signal of the comparison result, filter one of signals for a rising edge and a falling edge included in a signal of the edge detection result, and calculate the delay time based on a signal for the filtering result and the command signal.

According to an embodiment, the processor may identify a type of an edge first detected within a period of the command signal and determine a signal to be filtered according to the identified type.

According to another aspect of the present disclosure, a method of compensating for a phase delay of a resolver signal, which is performed in a computing device including a processor, includes receiving command signal and the resolver signal, calculating a delay time of the resolver signal with respect to the command signal based on the command signal and the resolver signal, calculating a compensation time based on the delay time, and compensating the command signal based on the compensation time.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating an apparatus for compensating for a phase delay of a resolver signal according to an embodiment of the present disclosure;

FIG. 2 is a block diagram illustrating a processor according to an embodiment of the present disclosure;

FIG. 3 is a diagram illustrating examples of a command signal, a resolver signal, and a delay time;

FIG. 4 is a diagram illustrating an example of a compensation time;

FIG. 5 is a diagram illustrating an example of a result of compensating a command signal;

FIG. 6 is a circuit diagram illustrating a delay time calculation module according to an embodiment of the present disclosure;

FIG. 7A-7B are diagrams illustrating an example of a filter module according to an embodiment of the present disclosure;

FIG. 8 is a timing diagram illustrating a delay time calculation module according to an embodiment of the present disclosure; and

FIG. 9 is a flowchart illustrating a method of compensating for a phase delay of a resolver signal according to an embodiment of the present disclosure.

### DETAILED DESCRIPTION

Hereinafter, an apparatus and a method for compensating for a phase delay of a resolver signal according to embodiments of the present disclosure will be described with reference to the accompanying drawings. In this process, the thicknesses of the lines and the sizes of the components shown in the drawings may be exaggerated for clarity and convenience of explanation. In addition, the terms described below are defined in consideration of the functions of the present disclosure, which may vary depending on the intention or custom of the user, the operator. Therefore, the definitions of these terms should be based on the contents throughout this specification.

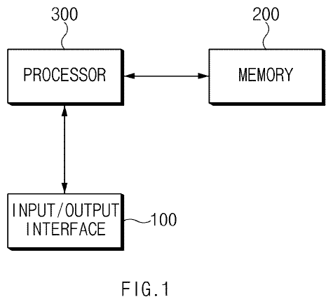

FIG. 1 is a block diagram illustrating an apparatus for compensating for a phase delay of a resolver signal according to an embodiment of the present disclosure.

Referring to FIG. 1, an apparatus 10 for compensating for a phase delay of a resolver signal (hereinafter, referred to as a compensation apparatus) according to an embodiment of the present disclosure may include an input/output interface 100, a memory 200, and a processor 300. Each component included in the compensation apparatus 10 may be connected through a common bus, or may be connected through an individual interface or an individual bus centered on the processor 300. The compensation apparatus 10 may further include various components in addition to those shown in FIG. 1, or some of the above components may be omitted.

The input/output interface 100 may receive data from an outside and output the data to the processor 300, which will be described later. In addition, the input/output interface 100 may output the results calculated by the processor 300 to the outside. The input/output interface 100 may be connected to a microcomputer 21 of a motor rotation angle detection device 20, and may receive a command signal output from the microcomputer 21, a resolver signal output from a resolver 23, and the like. The input/output interface 100 may be connected to a sine wave generator (excitation signal generator) 22 of the motor rotation angle detection device 20, and output the compensated command signal calculated by the processor 300 to the sine wave generator 22.

The memory 200 may store various information required during the operation of the processor 300. In addition, the memory 200 may store various information calculated during the operation of the processor 300.

The processor 300 may be operatively connected to the input/output interface 100 and the memory 200. The processor 300 may be implemented as a central processing unit (CPU), micro controller unit (MCU), or system on chip (SoC), drive an operating system or application to control a plurality of hardware or software components connected to the processor 300, perform various data processing and operations, execute at least one command stored in the memory 200, and store execution result data in the memory 200.

The processor 300 may receive a command signal and a resolver signal through the input/output interface 100, calculate a delay time of the resolver signal with respect to the command signal based on the received command signal and the resolver signal, calculate a compensation time based on the delay time, and compensate the command signal based on the compensation time.

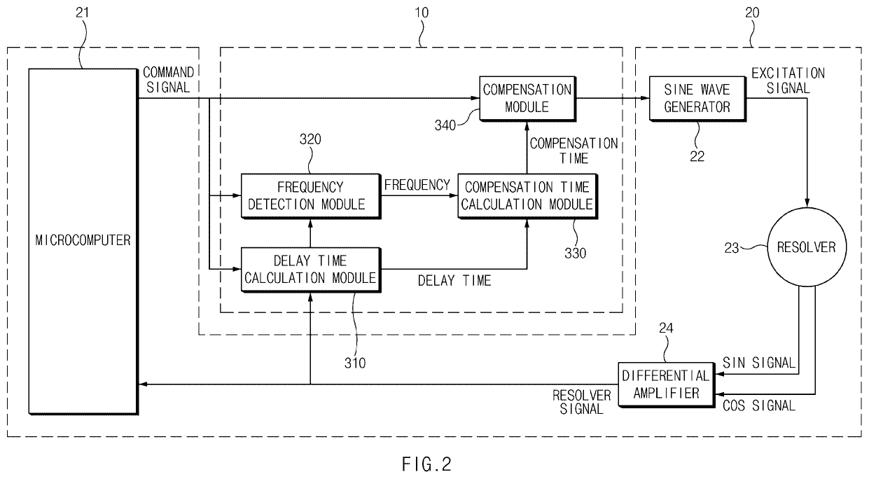

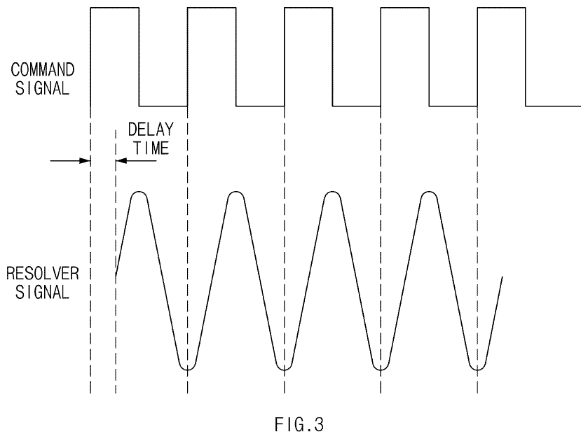

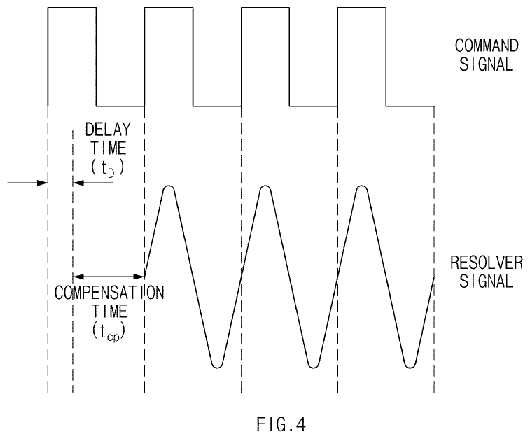

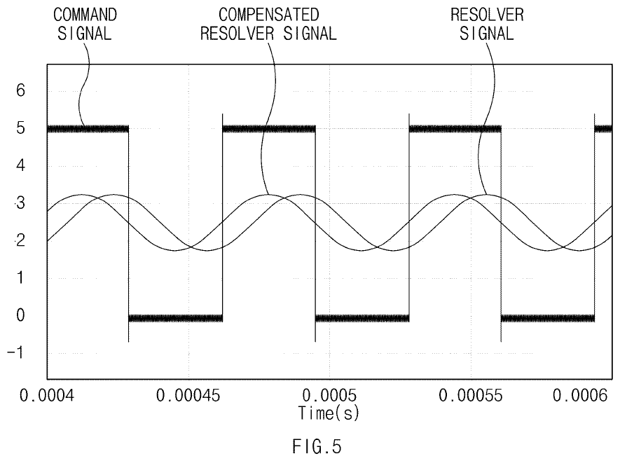

FIG. 2 is a block diagram illustrating a processor according to an embodiment of the present disclosure. FIG. 3 is a diagram illustrating examples of a command signal, a resolver signal, and a delay time. FIG. 4 is a diagram illustrating an example of a compensation time. FIG. 5 is a diagram illustrating an example of a result of compensating a command signal.

Referring to FIG. 2, the processor 300 may include a delay time calculation module 310, a frequency detection module 320, a compensation calculation module 330, and a compensation module 340. The modules indicated in this embodiment may be components responsible for some of the operations of the processor 300 classified according to function, and the operations performed by each module may be understood as operations performed by the processor 300.

The delay time calculation module 310 may receive a command signal and a resolver signal, and calculate the delay time of the resolver signal with respect to the command signal based on the command signal and the resolver signal. In this case, the command signal, which is a control signal output from the microcomputer 21, may be a square wave signal. The resolver signal, which is a signal output from the resolver 23 (specifically, a signal output from a differential amplifier 24 that changes a differential output signal (sin and cos signals) of the resolver 23 into a single output signal), may be an AC voltage proportional to the position of a rotor. As shown in FIG. 3, the delay time may correspond to the time difference between the command signal and the resolver signal measured based on the same phase. The delay time calculation module 310 may calculate an average value of the delay times calculated over a specified period (or number of times) and use the calculated average value as the final delay time. A specific scheme of calculating the delay time by the delay time calculation module 310 will be described later.

The frequency detection module 320 may receive a command signal and detect the frequency of the command signal based on the command signal. The frequency detection module 320 may oversample the command signal by using a frequency set to be greater than the frequency of the command signal and detect the frequency of the command signal by using the oversampling result. The frequency detection module 320 may be implemented with a digital counter or the like.

The compensation time calculation module 330 may calculate the compensation time based on the delay time calculated by the delay time calculation module 310 and the frequency of the command signal detected by the frequency detection module 320. The compensation time calculation module 330 may calculate the period of the command signal based on the frequency of the command signal, and calculate, as the compensation time, a value obtained by subtracting the delay time from the calculated period. As shown in FIG. 4, the compensation time may be a value obtained by subtracting the command time from the period of the command signal. The compensation time calculation module 330 may calculate the compensation time through following Equation 1.

$${t}_{CP} = ( \frac{1}{{f}_{C}} - {t}_{d} ) \qquad [ Equation 1 ]$$

Where t_{cp} is a compensation time, f_{c} is the frequency of a command signal, and t_{d} is a delay time.

The compensation module 340 may compensate the command signal output from the microcomputer 21 based on the compensation time calculated by the compensation time calculation module 330, and output the compensated command signal to the sine wave generator 22 of the motor rotation angle detection device 20. The compensation module 340 may synchronize the phases of the command signal and the resolver signal by delaying the command signal output from the microcomputer 21 by the compensation time. The sine wave generator 22 may generate an excitation signal according to the compensated command signal. When the command signal is delayed by the compensation time, the resolver signal may be delayed by the sum of the delay time and compensation time. As shown in FIG. 4, because the sum of the delay time and compensation time corresponds to one cycle of the command signal, when the command signal is delayed by the compensation time, as shown in FIG. 5, the phases of the resolver signal and the command signal may be synchronized.

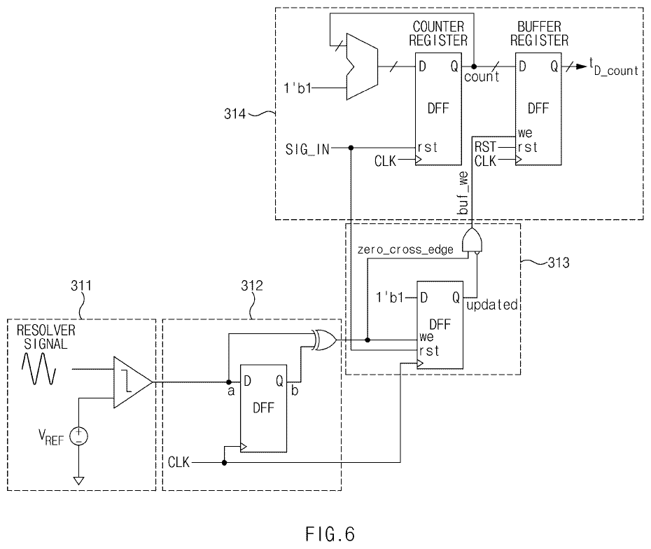

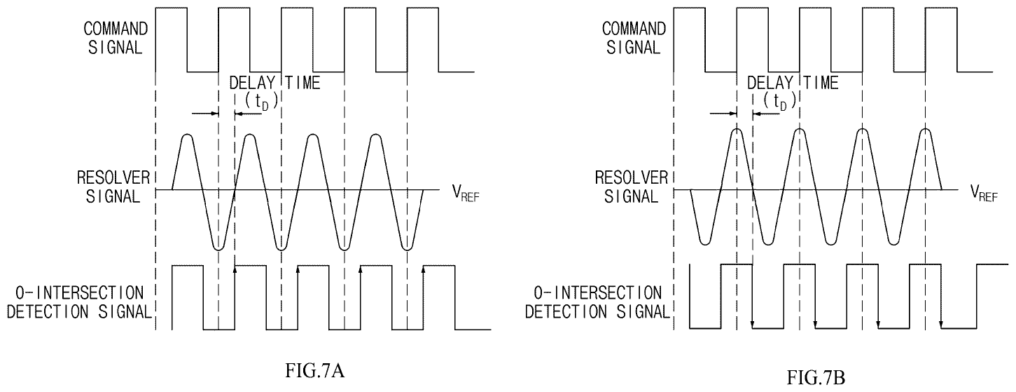

FIG. 6 is a circuit diagram illustrating a delay time calculation module according to an embodiment of the present disclosure. FIGS. 7A-7B are diagrams illustrating an example of a filter module according to an embodiment of the present disclosure.

Referring to FIG. 6, the delay time calculation module 310 may include a comparison module 311, an edge detection module 312, a filter module 313, and a counter module 314.

The comparison module 311 may compare the resolver signal output from the resolver 23 with a preset reference voltage and output the corresponding comparison result. In this case, the reference voltage may be 0 (zero) V. The comparison module 311 may output a logic high signal when the resolver signal is higher than the reference voltage, and may output a logic low signal when the resolver signal is less than the reference voltage.

The edge detection module 312 may detect an edge in a signal (i.e., 0-intersection) from the output signal of the comparison module 311 and output a corresponding edge detection result. The edge detection module 312 may output a logic high signal for a specified time when a rising edge or a falling edge occurs in the output signal of the comparison module 311. The edge detection module 312 may include a D flip-flop and an XOR operator.

The filter module 313 may filter one or more signals for the rising edge and the falling edge included in the output signal of the edge detection module 312 based on the command signal output from the microcomputer 21 and the output signal of the edge detection module 312. The output signal of the edge detection module 312 includes both a signal for the rising edge and a signal for the falling edge, and in order to calculate the delay time, it is necessary to filter and remove one of the signals for the rising edge and the falling edge. Accordingly, the filter module 313 may filter and remove one of the signals for the rising edge and the falling edge included in the output signal of the edge detection module 312. The filter module 313 may include a D flip-flop, a NOT operator, and an AND operator.

Meanwhile, as shown in FIGS. 7A-7B, the resolver signal may be inverted by 180 degrees depending on the angle of the motor. When the resolver signal is not inverted as shown in FIG. 7A, the delay time must be calculated based on the rising edge, and when the resolver signal is inverted and output as shown in FIG. 7B, the delay time must be calculated based on the falling edge. Accordingly, the filter module 313 may identify the type of an edge that is first detected within the period of the command signal, and determine which signal to be filtered among the signals for the rising edge and the falling edge according to the identified type.

When the edge first detected within the period of the command signal is a rising edge (i.e., when the resolver signal is not inverted), the filter module 313 may filter and remove a signal for a falling edge from the output signal of the edge detection module 312. On the other hand, when the edge first detected within the period of the command signal is a falling edge (i.e., when the resolver signal is output inverted), the filter module 313 may filter and remove a signal for a rising edge signal from the output signal of the edge detection module 312.

The counter module 314 may calculate the delay time of the resolver signal with respect to the command signal based on the command signal output from the microcomputer 21 and the output signal of the filter module 313. The counter module 314 may calculate the delay time of the resolver signal with respect to the command signal by counting the time from the start time point of the cycle of the command signal to the detection time point of the rising edge. The counter module 314 may include a multiplexer, a counter register, and a buffer register, and the counter register and the buffer register may include a dip-flop.

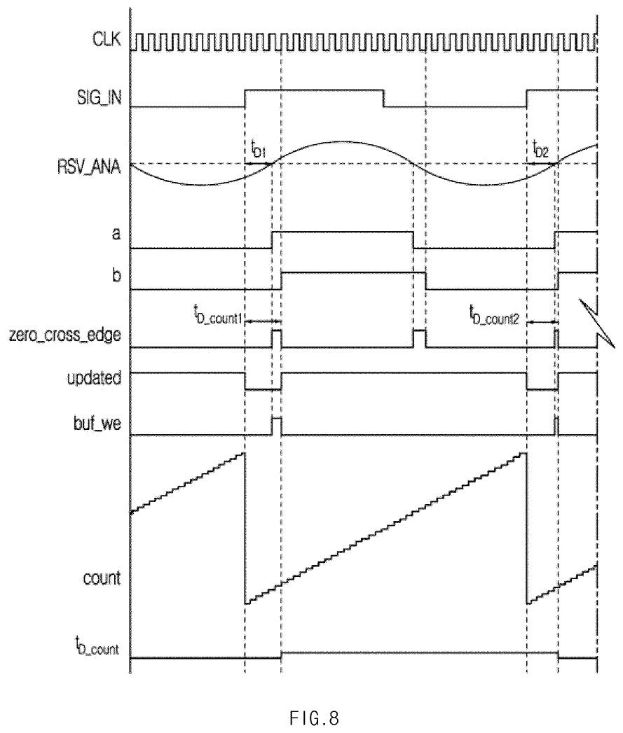

FIG. 8 is a timing diagram illustrating a delay time calculation module according to an embodiment of the present disclosure.

FIG. 8 illustrates a system clock CLK, a command signal SIG_IN output from the microcomputer 21, a resolver signal RSV_ANA output from the resolver 23, an input ‘a’ and an output ‘b’ of the D flip-flop included in the edge detection module 312, an output zero_cross_edge of the XOR operator included in the edge detection module 312, an output updated of the D flip-flop included in the filter module 313, an output buf_we of the AND operator of the filter module 313, an output count of the counter register included in the counter module 314, and an output t_{D} of the buffer register included in the counter module 314.

Referring to FIG. 8, ‘a’ may have a value of 1 when the resolver signal is higher than the reference voltage (0 V), and may have a value of 0 (zero) when the resolver signal is less than the reference voltage (0 V). ‘b’ may be obtained by delaying ‘a’ by a specified time. The zero_cross_edge may have a value of 1 when ‘a’ and ‘b’ do not match each other, and may have a value of 0 when ‘a’ and ‘b’ match each other.

The ‘updated’ may basically have a value of 1, but when the command signal SIG_IN changes from 0 to 1, the ‘updated’ may be reset and have a value of 0. When the ‘zero_cross_edge’ changes from 0 to 1, the ‘updated’ may be activated at a time point when delayed by a specified time from the point of change and have a value of 1. The ‘buf_we’ may have a value of 1 when the zero_cross_edge is 1 and the ‘updated’ is 0, and may have a value of 0 otherwise.

The ‘count’ may be initialized when SIG_IN changes from 0 to 1, and may have, as the value, the time elapsed from the time SIG_IN changes from 0 to 1. The t_{D_count} may have the count value from the time point when SIG_IN changes from 0 to 1 to the time point when but_we changes from 1 to 0, but may be updated according to but_we. The value of t_{D_count} may be used as the delay time.

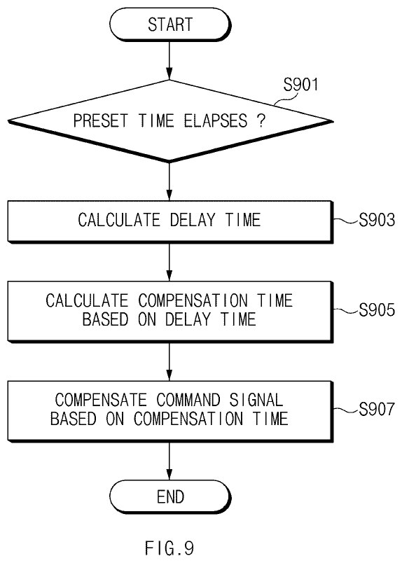

FIG. 9 is a flowchart illustrating a method of compensating for a phase delay of a resolver signal according to an embodiment of the present disclosure.

Hereinafter, a method of compensating for a phase delay of a resolver signal according to an embodiment of the present disclosure will be described with reference to FIG. 9. Some of the processes described later may be performed in an order different from the order described later or may be omitted.

First, in S901, the processor 300 may determine whether a preset time elapses from the time point when driving the motor. Because the resolver signal is unstable at the beginning of the motor operation, the delay time calculated from the resolver signal detected at the beginning of the motor operation may not be accurate. Therefore, in this embodiment, the delay time may be calculated after a specified time has elapsed from the time point when driving the motor, that is, after the current of the resolver 23 has been stabilized. The setting time (or the number of invalid pulses) may be set in advance through experiment or simulation. According to another embodiment, the processor 300 may receive a user input through the input/output interface 100 and set the setting time according to the received user input.

When a set time has elapsed from the time point when driving the motor, in S903, the processor 300 may calculate the delay time of the resolver signal with respect to the command signal based on the command signal and the resolver signal. Because the specific method of calculating the delay time has been described above, the detailed description will be omitted.

Next, in S905, the processor 300 may calculate the compensation time based on the delay time. The processor 300 may detect the frequency of the command signal, calculate the period of the command signal based on the detected frequency, and calculate, as the compensation time, a value obtained by subtracting the delay time from the calculated period.

Next, in S907, the processor 300 may compensate the command signal based on the compensation time. The processor 300 may synchronize the phases of the command signal and the resolver signal by delaying the command signal by the compensation time. The compensated command signal may be output to the sine wave generator 22, and the sine wave generator 22 may generate an excitation signal according to the compensated command signal and output the excitation signal to the resolver 23.

described above, the apparatus and method for compensating for a phase delay of a resolver signal may compensate for the phase delay of the resolver signal by calculating the delay time of the resolver signal with respect to the command signal output from the microcomputer and compensating the command signal according to the calculated delay time, so that the phase of the command signal is synchronized with the phase of the resolver signal.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Implementations described herein may be implemented, for example, as a method or process, device, software program, data stream, or signal. Although discussed only in the context of a single form of implementation (e.g., only as a method), implementations of the features discussed may also be implemented in other forms (e.g., devices or programs). The device may be implemented with appropriate hardware, software, firmware, and the like. The method may be implemented in a device such as a processor, which generally refers to a processing device that includes a computer, microprocessor, integrated circuit, or programmable logic device. Processors also include communication devices such as computers, cell phones, portable/personal digital assistants (“PDAs”) and other devices that facilitate communication of information between end-users.

According to aspects of the present disclosures, it is possible to compensate for the phase delay of the resolver signal by calculating the delay time of the resolver signal with respect to the command signal output from the microcomputer and compensating the command signal according to the calculated delay time, thereby synchronizing the phases of the command signal and the resolver signal.

Meanwhile, effects obtained by the embodiments of the disclosure may not be limited to the above, and other effects will be clearly understandable to those having ordinary skill in the art from the disclosures.

The present disclosure has been described with reference to the embodiments shown in the drawings, but this is merely illustrative. Therefore, it will be understood by those skilled in the art that various modifications and equivalent other embodiments of the present disclosure are possible therefrom. Accordingly, the true technical scope of the present disclosure should be defined by the technical spirit of the appended claims.

What is claimed is:

1. An apparatus for compensating for a phase delay of a resolver signal, the apparatus comprising:
an input/output interface; and
a processor connected to the input/output interface,
wherein the processor is configured to:
receive a command signal and a resolver signal through the input/output interface,
calculate a delay time of the resolver signal with respect to the command signal based on the command signal and the resolver signal,
calculate a compensation time based on the delay time, and
cause output of the command signal to be delayed by the compensation time.

2. The apparatus of claim 1, wherein the processor is configured to calculate the delay time in response to an elapse of a preset time that is calculated from a time point at which a motor is driven.

3. The apparatus of claim 1, wherein the processor is further configured to:
detect a frequency of the command signal,
calculate a period of the command signal based on the detected frequency, and
calculate, as the compensation time, a value by subtracting the delay time from the calculated period of the command signal.

4. The apparatus of claim 1, wherein the processor is further configured to synchronize a phase of the command signal and a phase of the resolver signal by delaying output of the command signal for the compensation time.

5. The apparatus of claim 1, wherein the processor is further configured to:
compare the resolver signal with a preset reference voltage and output a corresponding comparison result,
detect an edge in a signal from an output signal of the comparison result and output a corresponding edge detection result,
filter one or more signals for a rising edge and a falling edge included in a signal of an edge detection result, and
calculate the delay time of the resolver signal with respect to the command signal based on a signal for a filtering result and the command signal.

6. The apparatus of claim 5, wherein the processor is configured to identify a type of an edge first detected within a period of the command signal and determine the one or more signals to be filtered according to the identified type.

7. A method of compensating for a phase delay of a resolver signal, which is performed in a computing device including a processor, the method comprising:
receiving command signal and the resolver signal;
calculating a delay time of the resolver signal with respect to the command signal based on the command signal and the resolver signal;
calculating a compensation time based on the delay time; and
delaying output of the command signal by the compensation time.

8. The method of claim 7, wherein the calculating of the delay time includes calculating the delay time in response to an elapse of a preset time calculated from a time point at which a motor is driven.

9. The method of claim 7, wherein the calculating of the compensation time further includes detecting a frequency of the command signal, calculating a period of the command signal based on the detected frequency, and calculating, as the compensation time, a value obtained by subtracting the delay time from the calculated period as the compensation time.

10. The method of claim 7, wherein delaying output of the command signal by the compensation time results in a synchronizing of a phase of the command signal and a phase of the resolver signal.
